(19) United States
(12) Patent Application Publication
(10) Pub. No.: US 2014/0092562 A1
(43) Pub. Date: Apr. 3, 2014

(54) INSULATION AND HEAT RADIATION STRUCTURE OF POWER DEVICE, CIRCUIT BOARD, AND POWER SUPPLY APPARATUS

(71) Applicant: HUAWEI TECHNOLOGIES CO., LTD., Shenzhen (CN)

(72) Inventors: Yan XU, Shenzhen (CN); Baoguo Chen, Shenzhen (CN); Guoyuan Zhao, Shenzhen (CN)

(73) Assignee: HUAWEI TECHNOLOGIES CO., LTD., Shenzhen (CN)

(21) Appl. No.: 14/100,374

(22) Filed: Dec. 9, 2013

Related U.S. Application Data
(63) Continuation of application No. PCT/CN2012/083946, filed on Nov. 2, 2012.

(30) Foreign Application Priority Data
Jan. 11, 2012 (CN) 201210007075.3

(51) Int. Cl. H05K 7/20

(52) U.S. Cl. CPC H05K 7/209
USPC 361/720; 361/704

(57) ABSTRACT

Embodiments of the present application provide an insulation and heat radiation structure of a power device, a circuit board, and a power supply apparatus. The insulation and heat radiation structure of the power device includes a power device, an insulation ceramic piece, and a heat radiator, where the power device is of a sheet structure, the insulation ceramic piece is an alumina ceramic piece, a heat radiator pin is disposed on the heat radiator, the heat radiator pin is used for being mechanically connected to the circuit board, a heating surface of the power device is adhesively fixed to one surface of the insulation ceramic piece through a first insulating thermal conductive adhesive, and the other surface of the insulation ceramic piece is adhesively fixed to a contact heat radiation surface of the heat radiator through a second insulating thermal conductive adhesive.

### CROSS-REFERENCE TO RELATED APPLICATIONS

This application is a continuation of International Application No. PCT/CN2012/083946, filed on Nov. 2, 2012, which claims priority to Chinese Patent Application No. 201210007075.3, filed on Jan. 11, 2012, both of which are hereby incorporated by reference in their entireties.

### FIELD OF THE APPLICATION

The present application relates to the field of power supply products, and in particular, to an insulation and heat radiation structure of a power device, a circuit board, and a power supply apparatus.

### BACKGROUND OF THE APPLICATION

Power devices such as a power switch tube and a rectifier are widely applied in a power supply product, where installation of the power device should meet requirements of both heat radiation and insulation. A space occupied by the insulation and heat radiation structure of the power device is a key factor affecting a power density of a power supply apparatus.

In the power supply product, a common insulation and heat radiation structure of the power device is formed by a screw, an insulating particle, a power device, and a heat radiator, where the power device is fixed on a contact heat radiation surface of the heat radiator through the screw and the insulating particle. Another common insulation and heat radiation structure of the power device is formed by an elastic batten, a power device, and a heat radiator, where the power device is clamped on a contact heat radiation surface of the heat radiator through the elastic batten.

In the insulation and heat radiation structures of the power device, by fixing the power device on the contact heat radiation surface of the heat radiator through the screw and the insulating particle or by clamping the power device on the contact heat radiation surface of the heat radiator through the elastic batten, the space occupied by the insulation and heat radiation structure of the power device is great, thereby decreasing the power density of the power supply apparatus.

### SUMMARY OF THE APPLICATION

Embodiments of the present application provide an insulation and heat radiation structure of a power device, a circuit board, and a power supply apparatus, where the insulation and heat radiation structure occupies a small space, thereby significantly improving a power density of the power supply apparatus.

An insulation and heat radiation structure of a power device includes:

a power device, an insulation ceramic piece, and a heat radiator, where

the power device is of a sheet structure, the insulation ceramic piece is an alumina ceramic piece, a heat radiator pin is disposed on the heat radiator, and the heat radiator pin is used for being mechanically connected to a circuit board; and

the power device, the insulation ceramic piece, and the heat radiator are sequentially fixed in a transverse direction, a heating surface of the power device is adhesively fixed to one surface of the insulation ceramic piece through a first insulating thermal conductive adhesive, and the other surface of the insulation ceramic piece is adhesively fixed to a contact heat radiation surface of the heat radiator through a second insulating thermal conductive adhesive.

A circuit board includes an insulation and heat radiation structure of a power device formed by a power device, an insulation ceramic piece, and a heat radiator, where the power device is of a sheet structure, the insulation ceramic piece is an alumina ceramic piece, the power device, the insulation ceramic piece, and the heat radiator are sequentially fixed in a transverse direction, a heating surface of the power device is adhesively fixed to one surface of the insulation ceramic piece through a first insulating thermal conductive adhesive, the other surface of the insulation ceramic piece is adhesively fixed to a contact heat radiation surface of the heat radiator through a second insulating thermal conductive adhesive, a heat radiator pin is disposed on the heat radiator, and the heat radiator pin is mechanically connected to the circuit board.

A power supply apparatus is provided, where the foregoing circuit board and a power supply board are disposed inside the power supply apparatus, and a power supply output pin of the power supply board is electrically connected to a power supply input pin of the circuit board.

In the insulation and heat radiation structure of the power device provided by the embodiments of the present application, the heating surface of the power device is adhesively fixed to one surface of the insulation ceramic piece through the first insulating thermal conductive adhesive and the other surface of the insulation ceramic piece is adhesively fixed to the contact heat radiation surface of the heat radiator through the second insulating thermal conductive adhesive, thereby meeting heat radiation and insulation requirements of the power device. In addition, a space occupied by the insulation and heat radiation structure of the power device can be decreased through the adhesive fixing of the insulating thermal conductive adhesive, thereby significantly improving the power density of the power supply apparatus.

### BRIEF DESCRIPTION OF THE DRAWINGS

To describe the technical solutions in the embodiments of the present application more clearly, the following briefly describes the accompanying drawings required for describing the embodiments of the present application. Apparently, the accompanying drawings in the following description show merely some embodiments of the present application, and persons of ordinary skill in the art may still derive other drawings from these accompanying drawings without creative efforts.

FIG. 1 is a schematic view of an insulation and heat radiation structure of a power device provided by an embodiment of the present application;

FIG. 2 is a schematic view of installation of the insulation and heat radiation structure of a power device shown in FIG. 1 and a circuit board;

FIG. 3 is a schematic view of arrangement of two adjacent insulation ceramic pieces provided by an embodiment of the present application; and

FIG. 4 is a schematic view of a combined insulation ceramic piece provided by an embodiment of the present application.

### DETAILED DESCRIPTION OF THE EMBODIMENTS

The following clearly describes the technical solutions in the embodiments of the present application with reference to the accompanying drawings in the embodiments of the present application. Apparently, the described embodiments are merely a part rather than all of the embodiments of the present application. All other embodiments obtained by persons of ordinary skill in the art based on the embodiment of the present application without creative efforts shall fall within the protection scope of the present application.

Embodiments of the present application provide an insulation and heat radiation structure of a power device, a circuit board, and a power supply apparatus, where the insulation and heat radiation structure occupies a small space, thereby significantly improving a power density of the power supply apparatus. The details are described respectively in the following.

### Embodiment 1

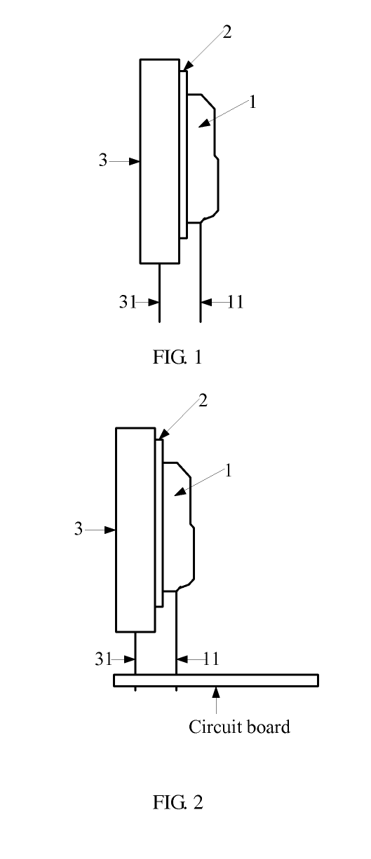

Referring to FIG. 1, FIG. 1 is a schematic view of an insulation and heat radiation structure of a power device according to Embodiment 1 of the present application. As shown in FIG. 1, the insulation and heat radiation structure of the power device may include:

a power device 1, an insulation ceramic piece 2, and a heat radiator 3, where

the power device 1 is of a sheet structure, the insulation ceramic piece 2 is an alumina ceramic piece, and the heat radiator 3; and

the power device 1, the insulation ceramic piece 2, and the heat radiator 3 are sequentially fixed in a transverse direction, a heating surface of the power device 1 is adhesively fixed to one surface of the insulation ceramic piece 2 through a first insulating thermal conductive adhesive, and the other surface of the insulation ceramic piece 2 is adhesively fixed to a contact heat radiation surface of the heat radiator 3 through a second insulating thermal conductive adhesive.

The insulation and heat radiation structure of the power device shown in FIG. 1 may be applied to various power supply apparatuses and other modules with a power management function, such as a transformer module. A switching power supply is taken as an example. Multiple types of power devices with different package types, such as a power switch tube and a rectifier bridge, need to be used in a circuit board of the switching power supply. The power devices may have pins, and the typical package types are TO220, TO247, TO264, and the like. Generally, the heat of an internal chip of the power device is radiated to the outside through a chip bottom. That is, the heating surface of the foregoing power device 1 may be a chip bottom of an internal chip of the power device 1 (the heat is radiated to the outside through the chip bottom).

In the insulation and heat radiation structure of the power device shown in FIG. 1, a power device pin 11 may be disposed on the power device 1, and the power device pin 11 is used for being electrically connected to the circuit board, so as to achieve electrical interconnection between the power device 1 and the circuit board.

In the insulation and heat radiation structure of the power device shown in FIG. 1, a heat radiator pin 31 may be disposed on the heat radiator 3, and the heat radiator pin 31 is used for being mechanically connected to the circuit board, so as to achieve mechanical connection between the heat radiator 3 and the circuit board. In an embodiment, multiple heat radiator pins 31 may be disposed on the heat radiator 3, corresponding welding via holes may be disposed on the circuit board, and the heat radiator 3 to which the power device 1 is adhesively fixed is inserted on the circuit board, so that the power device pin 11 and the heat radiator pin 31 can be welded on the circuit board at the same time, as shown in FIG. 2.

The circuit board shown in FIG. 2 may be disposed inside various power supply apparatuses, thereby significantly improving the power density of the power supply apparatus.

When the circuit board shown in FIG. 2 is disposed inside various power supply apparatuses, a power supply output pin of a power supply board inside the various power supply apparatuses may be electrically connected to a power supply input pin of the circuit board, so as to supply power to the circuit board.

In the insulation and heat radiation structure of the power device provided by the embodiment of the present application, the number of the insulation ceramic pieces 2 is at least 2, and a distance between two adjacent insulation ceramic pieces is greater than 3 mm, where 3 mm is a safe creepage distance. At least one power device 1 is adhesively fixed to one surface of each insulation ceramic piece 2. That is, multiple power devices 1 may be adhesively fixed to one insulation ceramic piece 2 at the same time, and multiple insulation ceramic pieces 2 may be adhesively fixed to one heat radiator 1 at the same time.

As an optional implementation mode, the insulation ceramic piece 2 may be an alumina ceramic piece with a thermal conductivity coefficient greater than 20 w/mk. According to application requirements, a thickness of the alumina ceramic piece (that is, the insulation ceramic piece 2) usually ranges from 0.5 mm to 2 mm.

As an optional implementation mode, the heat radiator 3 may be a metal heat radiator (for example, a heat radiator made of a material such as aluminum or copper). In an embodiment, the heat radiator 3 may also be a micro-pore ceramic heat radiation piece. Because of a micro-pore structure, pores in a surface area of the micro-pore ceramic heat radiation piece are 30% more than that of a metal heat radiator. Therefore, the micro-pore ceramic heat radiation piece has a larger area of contact with convective medium air and is capable of taking more heat away in the same unit time.

As an optional implementation mode, the first insulating thermal conductive adhesive and the second insulating thermal conductive adhesive may be organic insulating thermal conductive adhesives with a thermal conductivity coefficient greater than 0.3 w/mk. The organic insulating thermal conductive adhesive is usually formed by adding a certain quantity of insulating thermal conductive fillers (such as alumina, silicon dioxide, aluminum nitride, boron nitride, and zinc oxide) in organic resin (such as epoxy, silicone, and polyacrylic acid).

In particular, for the second insulating thermal conductive adhesive used for adhesively fixing the insulation ceramic piece 2 (such as the alumina ceramic piece) and the heat radiator 3, because of a great difference between coefficients of thermal expansion (Coefficients Of Thermal Expansion, CTE) of the insulation ceramic piece 2 (such as the alumina ceramic piece) and the heat radiator 3 (such as an aluminum radiator or a copper radiator), the second insulating thermal conductive adhesive should be an organic insulating thermal conductive adhesive with an as-small-as-possible thermal conductive adhesive modulus. Experiments show that, the best adhesive fixing effect can be achieved when the second insulating thermal conductive adhesive is an organic insulating thermal conductive adhesive with a thermal conductivity coefficient greater than 0.3 w/mk and a thermal conductive adhesive modulus less than 5 GPa after cured at a temperature of 25° C.

As an optional implementation mode, the first insulating thermal conductive adhesive may also be an organic insulating thermal conductive adhesive with a thermal conductivity coefficient greater than 0.3 w/mk and a thermal conductive adhesive modulus less than 5 GPa after cured at a temperature of 25° C.

In the embodiment of the present application, insulating thermal conductive adhesives are coated on surfaces of the heat radiator 3 and the insulation ceramic piece 2. With an assistant tool, the power device 1, the insulation ceramic piece 2 coated with the insulating thermal conductive adhesive, and the heat radiator 3 coated with the insulating thermal conductive adhesive are mounted sequentially, and the insulating thermal conductive adhesives are cured in a specified high temperature baking condition, thereby implementing the adhesive fixing of the heat radiator 3, the insulation ceramic piece 2, and the power device 1.

In Embodiment 1 of the present application, the heating surface of the power device 1 is adhesively fixed to one surface of the insulation ceramic piece 2 through the first insulating thermal conductive adhesive and the other surface of the insulation ceramic piece 2 is adhesively fixed to the contact heat radiation surface of the heat radiator 3 through the second insulating thermal conductive adhesive, thereby meeting heat radiation and insulation requirements of the power device 1. In addition, a space occupied by the insulation and heat radiation structure of the power device 1 can be decreased through the adhesive fixing of the insulating thermal conductive adhesive, thereby significantly improving the power density of the power supply apparatus.

### Embodiment 2

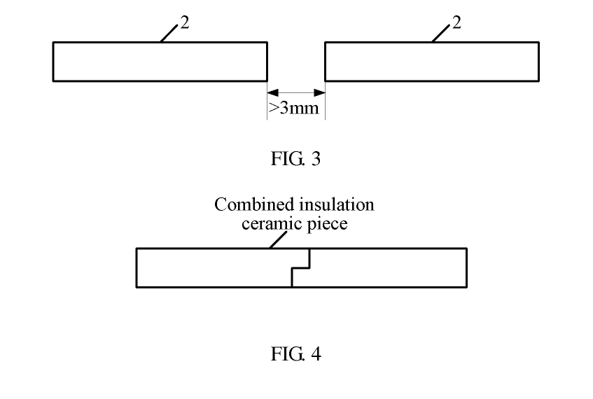

In Embodiment 2 of the present application, it is assumed that four TO247 power switch tubes are adhesively fixed by using two insulation ceramic pieces 2. Compared with the adhesive fixing of four TO247 power switch tubes by using one insulation ceramic piece 2, the adhesive fixing by using two insulation ceramic pieces 2 needs to add a certain distance between the two insulation ceramic pieces 2 to meet a requirement of a safe creepage distance, as shown in FIG. 3.

In the embodiment of the present application, to decrease a space occupied by an insulation and heat radiation structure of a power device to a greater extent, the larger the number of the power devices adhered to the same insulation ceramic piece is, the more significant the effect of saving the occupied space is. The larger the number of the power devices sharing the insulation ceramic piece is, the larger a size of the insulation ceramic piece is. The larger the size of the insulation ceramic piece is, the larger the thermal stress generated due to a temperature change is. Therefore, it is possible that the insulation ceramic piece is cracked due to the stress or the ceramic piece comes off the heat radiator, so that a power supply product is useless. Embodiment 2 of the present application provides a solution of a combined insulation ceramic piece. The combined insulation ceramic piece does not increase the occupied space significantly and meanwhile does not decrease the adhesion reliability of the insulation ceramic piece. That eight TO247 power switch tubes share one insulation ceramic piece is taken as an example. If the size of the insulation ceramic piece is excessively large, and a risk of the adhesion reliability of the insulation ceramic piece is great. In the embodiment of the present application, the combined insulation ceramic piece shown in FIG. 4 may be used to replace a single insulation ceramic piece. Compared with the whole single insulation ceramic piece, the combined insulation ceramic piece shown in FIG. 4 has only half of the thermal stress of the whole single insulation ceramic piece and does not increase the occupied space.

### Embodiment 3

In Embodiment 3 of the present application, the first insulating thermal conductive adhesive and the second insulating thermal conductive adhesive may be organic insulating thermal conductive films, so as to avoid manual coating of insulating thermal conductive adhesives, thereby improving production efficiency. A middle part of an organic insulating thermal conductive film may be a glass fiber cloth substrate, or a PI insulating and pressure-resistant film, or a PEN insulating and pressure-resistant film, and two surfaces are disposed with a pre-cured thermal conductive adhesive. The organic insulating thermal conductive film may not have a substrate, and may be a thermal conductive adhesive film coated into a sheet shape. The organic insulating thermal conductive film may be cured for the second time after being heated at a high temperature, so as to implement the adhesive fixing of the power device 1, the insulation ceramic piece 2, and the heat radiator 3.

Compared with the existing insulation and heat radiation structure of the power device, the embodiment of the present application can decrease the space occupied by the single insulation and heat radiation structure of the power device by approximately 50%, thereby significantly improving a power density of the whole power supply product.

The insulation and heat radiation structure of the power device provided by the embodiments of the present application is described in detail in the foregoing. The principle and implementation of the present application are described herein through specific examples. The description about the embodiments of the present application is merely provided for ease of understanding of the present application. Persons of ordinary skill in the art can make variations to the present application in terms of the specific implementations and application scopes according to the idea of the present application. Therefore, the specification shall not be construed as a limit to the present application.

1. An insulation and heat radiation structure of a power device, comprising:
a power device, an insulation ceramic piece, and a heat radiator, wherein
the power device is of a sheet structure, the insulation ceramic piece is an alumina ceramic piece, a heat radiator pin is disposed on the heat radiator, and the heat radiator pin is used for being mechanically connected to a circuit board; and
the power device, the insulation ceramic piece, and the heat radiator are sequentially fixed in a transverse direction, a heating surface of the power device is adhesively fixed to one surface of the insulation ceramic piece through a first insulating thermal conductive adhesive, and the other surface of the insulation ceramic piece is adhesively fixed to a contact heat radiation surface of the heat radiator through a second insulating thermal conductive adhesive.

2. The insulation and heat radiation structure according to claim 1, wherein the insulation ceramic piece has a thermal conductivity coefficient greater than approximately 20 w/mk and a thickness of approximately 0.5 mm to approximately 2 mm.

3. The insulation and heat radiation structure according to claim 1, wherein the heat radiator is a metal heat radiator.

4. The insulation and heat radiation structure according to claim 1, wherein the first insulating thermal conductive adhesive is an organic insulating thermal conductive adhesive with a thermal conductivity coefficient greater than approximately 0.3 w/mk and a thermal conductive adhesive modulus less than approximately 5 GPa after cured at a temperature of approximately 25° C.

5. The insulation and heat radiation structure according to claim 1, wherein the first insulating thermal conductive adhesive is an organic insulating thermal conductive film, and the organic insulating thermal conductive film is a thermal conductive adhesive processed into a sheet shape in a coating manner.

6. The insulation and heat radiation structure according to claim 1, wherein the second insulating thermal conductive adhesive is an organic insulating thermal conductive adhesive with a thermal conductivity coefficient greater than approximately 0.3 w/mk and a thermal conductive adhesive modulus less than approximately 5 GPa after cured at a temperature of approximately 25° C.

7. The insulation and heat radiation structure according to claim 1, wherein the second insulating thermal conductive adhesive is an organic insulating thermal conductive film, and the organic insulating thermal conductive film is a thermal conductive adhesive processed into a sheet shape in a coating manner.

8. The insulation and heat radiation structure according to claim 1, wherein the insulation ceramic piece is a combined insulation ceramic piece.

9. The insulation and heat radiation structure according to claim 1, wherein a power device pin is disposed on the power device, and the power device pin is used for being electrically connected to the circuit board.

10. The insulation and heat radiation structure according to claim 1, wherein the number of the insulation ceramic pieces is at least 2, and a distance between two adjacent insulation ceramic pieces meets a requirement of a safe creepage distance.

11. The insulation and heat radiation structure according to claim 10, wherein at least one power device is adhesively fixed to one surface of each insulation ceramic piece.

12. A circuit board, comprising an insulation and heat radiation structure of a power device formed by a power device, an insulation ceramic piece, and a heat radiator, wherein the power device is of a sheet structure, the insulation ceramic piece is an alumina ceramic piece, the power device, the insulation ceramic piece, and the heat radiator are sequentially fixed in a transverse direction, a heating surface of the power device is adhesively fixed to one surface of the insulation ceramic piece through a first insulating thermal conductive adhesive, the other surface of the insulation ceramic piece is adhesively fixed to a contact heat radiation surface of the heat radiator through a second insulating thermal conductive adhesive, a heat radiator pin is disposed on the heat radiator, and the heat radiator pin is mechanically connected to the circuit board.

13. The circuit board according to claim 12, wherein the insulation ceramic piece has a thermal conductivity coefficient greater than approximately 20 w/mk and a thickness of approximately 0.5 mm to approximately 2 mm.

14. The circuit board according to claim 12, wherein the heat radiator is a metal heat radiator.

15. The circuit board according to claim 12, wherein the first insulating thermal conductive adhesive is an organic insulating thermal conductive adhesive with a thermal conductivity coefficient greater than approximately 0.3 w/mk and a thermal conductive adhesive modulus less than approximately 5 GPa after cured at a temperature of approximately 25° C.

16. The circuit board according to claim 12, wherein the first insulating thermal conductive adhesive is an organic insulating thermal conductive film, and the organic insulating thermal conductive film is a thermal conductive adhesive processed into a sheet shape in a coating manner.

17. The circuit board according to claim 12, wherein the second insulating thermal conductive adhesive is an organic insulating thermal conductive adhesive with a thermal conductivity coefficient greater than approximately 0.3 w /mk and a thermal conductive adhesive modulus less than approximately 5 GPa after cured at a temperature of approximately 25° C.

18. The circuit board according to claim 12, wherein the second insulating thermal conductive adhesive is an organic insulating thermal conductive film, and the organic insulating thermal conductive film is a thermal conductive adhesive processed into a sheet shape in a coating manner.

19. The circuit board according to claim 12, wherein a power device pin is disposed on the power device, and the power device pin is electrically connected to the circuit board.

20. A power supply apparatus, comprising:
a circuit board and a power supply board both being disposed inside the power supply apparatus, and a power supply output pin of the power supply board electrically connected to a power supply input pin of the circuit board, wherein: the circuit board comprises an insulation and heat radiation structure of a power device formed by a power device, an insulation ceramic piece, and a heat radiator, wherein the power device is of a sheet structure, the insulation ceramic piece is an alumina ceramic piece, the power device, the insulation ceramic piece, and the heat radiator are sequentially fixed in a transverse direction, a heating surface of the power device is adhesively fixed to one surface of the insulation ceramic piece through a first insulating thermal conductive adhesive, the other surface of the insulation ceramic piece is adhesively fixed to a contact heat radiation surface of the heat radiator through a second insulating thermal conductive adhesive, a heat radiator pin is disposed on the heat radiator, and the heat radiator pin is mechanically connected to the circuit board.
